(19) United States
(12) Patent Application Publication
(10) Pub. No.: US 2013/0240928 A1
(43) Pub. Date: Sep. 19, 2013

(54) OPTICAL LENS AND LIGHT EMITTING DIODE PACKAGE USING THE SAME

(71) Applicant: YAU-TZU JANG, Hukou (TW)

(72) Inventor: YAU-TZU JANG, Hukou (TW)

(21) Appl. No.: 13/658,106

(22) Filed: Oct. 23, 2012

(30) Foreign Application Priority Data
Mar. 19, 2012 (CN) 2012100721097

(51) Int. Cl. F21V 13/04; H01L 33/60

(52) U.S. Cl. 257/98; 362/327; 257/E33.072

(57) ABSTRACT

An LED package includes an LED light source and an optical lens located over the LED light source. The optical lens includes a top surface, a light reflective lateral surface and a bottom surface receiving the LED light source therein. The top surface includes a reflection surface located in the middle of the top surface and a refraction surface surrounding the reflection surface. The top surface receives light emitted from the LED light source, and the light striking the reflection surface is firstly reflected towards the lateral surface by the reflection surface, secondly reflected towards the refraction surface by the lateral surface, and finally refracted out of the optical lens by the refraction surface.

### BACKGROUND

1. Technical Field

The present disclosure relates to an optical lens, and particularly to a light emitting diode (LED) package using the same whereby the LED package can have increased light output in lateral direction.

2. Description of Related Art

LEDs have been widely promoted as light sources of electronic devices owing to many advantages, such as high luminosity, low operational voltage and low power consumption. However, a viewing angle of light generated by the LED is 90° to 120° (±45° to ±60°) which causes the light to be too intensive at the forward direction and too weak at the lateral direction, whereby the LED is not suitable for use in illumination.

Therefore, an optical lens and an LED package using the optical lens which are capable of overcoming the above described shortcomings are desired.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

The only drawing shows a schematic, cross sectional view of an LED package having an optical lens in accordance with an embodiment of the present disclosure.

### DETAILED DESCRIPTION

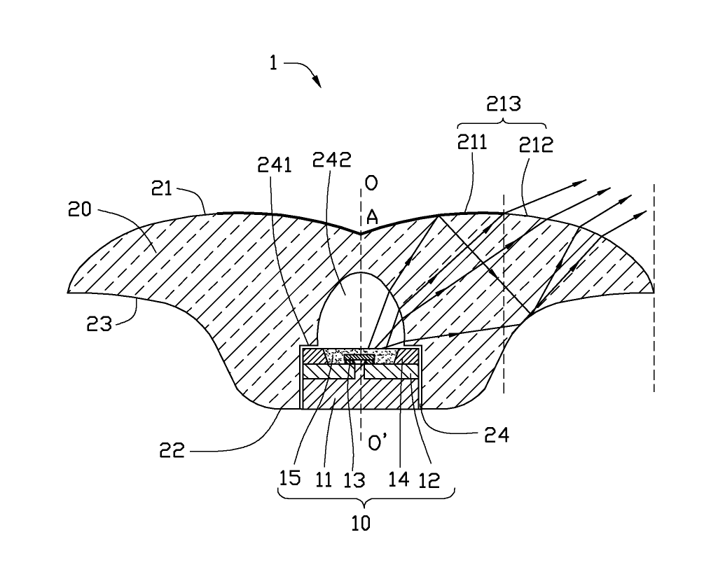

Referring to FIG. 1, an LED package 1 in accordance with an embodiment of the present disclosure includes an LED light source 10 and an optical lens 20 located on the light path of the LED light source 10.

In this embodiment, the LED light source 10 includes a substrate 11 with an electrode structure 12, an LED chip 13 mounted on and electrically connected to the electrode structure 12, a reflection cup 14 surrounding the LED chip 13, and an encapsulation layer 15 received in the reflection cup 14 and sealing the LED chip 13 therein. The electrode structure 12 consists of an anode and a cathode. The LED chip 13 is mounted to the electrode structure 12 by flip chip. The encapsulation layer 15 includes a resin and fluorescent particles dispersed in the resin whereby light generated by the LED chip 13 can be converted to another light having a desired color, for example, white.

The optical lens 20 is located over the LED light source 10 and receives the LED light source 10 therein. The optical lens 20 is used for changing the light path of the light from the LED light source 10. The optical lens 20 is made of transparent material with superior optical performance, such as glass, PMMA (polymethylmethacrylate) or PC (polycarbonate). In this embodiment, the optical lens 20 is symmetrically configured around a central axis OO′ thereof, which is coincided with a central axis of the LED light source 10. To describe conveniently, a radial direction of the optical lens 20 is defined as a direction perpendicular to the central axis OO′ and away from the central axis OO′. “Radial direction” and “lateral direction” are synonymous in the disclosure.

The optical lens 20 includes a top surface 21, a bottom surface 22 below the top surface 21 and a lateral surface 23 interconnecting the top surface 21 and the bottom surface 22. The lateral surface 23 is located below the top surface 21 and above the bottom surface 22.

A middle of the top surface 21 is recessed downward to a point A. The central axis OO′ of the optical lens 20 extends through the point A. A peripheral portion around the point A of the top surface 21 is convex along an upward direction. The top surface 21 includes a reflection surface 211 containing the point A and a refraction surface 212 surrounding the reflection surface 211. Light emitted from the LED light source 10 is refracted when passing through the refraction surface 212 and reflected when impinging the reflection surface 211. In this embodiment, the point A is configured on the central axis OO′ of the optical lens 20, and the reflection surface 211 and the refraction surface 212 cooperatively form a smooth, convex and annular surface 213 around the point A. The reflection surface 211 is coated with reflective material such as silver. Preferably, a length of a projection of the reflection surface 211 on the horizontal plane and along the radial direction is equal to that of the refraction surface 212. Alternatively, the lengths of the projections of the reflection surface 211 and the refraction surface 212 on the horizontal plane and along the radial direction can be adjusted according to the actual requirement.

The bottom surface 22 is flat, and a length of the bottom surface 22 along the radial direction is smaller than that of the top surface 21. The middle of the bottom surface 22 is concaved upwardly and defines a receiving groove 24 for receiving the LED light source 10 therein. The receiving groove 24 defines a surface 241 away from the bottom surface 22, and the surface 241 is concaved upwardly and defines a cavity 242 above the receiving groove 24. In this embodiment, the receiving groove 24 and the cavity 242 are both symmetrical in regard to the central axis OO′. The cavity 242 is generally semi-ellipsoid shaped, and a length of a major axis of an ellipsoid defining the cavity 242 which is along the central axis OO′ is 1.5-2.5 times of a length of a minor axis of the ellipsoid.

The lateral surface 23 interconnects the top surface 21 and the bottom surface 22, and the lateral surface 23 is a smooth curve and concaved towards to the top surface 21. The curvature radius of the lateral surface 23 is greater than that of the annular surface 213 of the top surface 21. The lateral surface 23 is coated with reflection material, such as silver.

During operation of the LED light source 10, the light emitted from the LED light source 10 travels toward the optical lens 20 via the cavity 242. A part of the light which strikes the reflection surface 211 of the top surface 21 is firstly reflected by the reflection surface 211 toward the lateral surface 23 of the optical lens 20 and then is reflected by the lateral surface 23 toward the refraction surface 212 of the top surface 21. The light is finally refracted by the refraction surface 212 to travel out of the optical lens 20. The other part of the light which directly strikes the refraction surface 212 of the top surface 21 is refracted by the refraction surface 212 to travel out of the optical lens 20. Therefore, the optical lens 20 guides the light emitted from the LED light source 10 to lateral sides thereof, and therefore the light intensity of the light from the LED package 1 at the lateral direction is increased.

A particular embodiment is shown and described by way of illustration only. The principles and the features of the present disclosure may be employed in various and numerous embodiments thereof without departing from the scope of the disclosure as claimed. The above-described embodiment illustrates the scope of the disclosure but does not restrict the scope of the disclosure.

What is claimed is:

1. An optical lens for guiding light generated from an LED light source to a lateral direction, comprising
a curved top surface, the top surface comprising a reflection surface located at the middle of the top surface and a refraction surface surrounding the reflection surface;
a bottom surface below the top surface, the bottom surface defining a receiving groove configured for receiving the LED light source therein; and
a light reflective lateral surface located below the top surface and above the bottom surface, the light reflective lateral surface interconnecting the top surface and the bottom surface;
wherein the top surface is configured for receiving light emitted from the LED light source, and the light striking the reflection surface of the top surface is firstly reflected towards the light reflective lateral surface by the reflection surface, secondly reflected towards the refraction surface by the light reflective lateral surface, and finally refracted out of the optical lens by the refraction surface.

2. The optical lens of claim 1, wherein a projection length of the reflection surface on a horizontal plane and along a radial direction of the optical lens is equal to that of the refraction surface.

3. The optical lens of claim 1, wherein the receiving groove is concaved upwardly from a middle of the bottom surface.

4. The optical lens of claim 3, wherein the receiving groove defines a surface away from the bottom surface, and the surface is concaved upwardly to define a cavity above the receiving groove.

5. The optical lens of claim 4, wherein the cavity is semi-ellipsoid shaped.

6. The optical lens of claim 5, wherein a length of a major axis of an ellipsoid defining the cavity which is along a central axis of the optical lens is 1.5-2.5 times of a length of a minor axis of the ellipsoid.

7. The optical lens of claim 1, wherein the optical lens is symmetrically configured about a central axis of the optical lens, a middle of the top surface is recessed downward to a point, a peripheral portion around the point of the top surface is convex along an upward direction, and the central axis of the optical lens extends through the point.

8. The optical lens of claim 7, wherein the reflection surface and the refraction surface cooperatively form a smooth, convex, annular surface.

9. The optical lens of claim 8, wherein the lateral surface is a smooth curve and concaved towards to the top surface, and the curvature radius of the lateral surface is greater than that of the smooth, convex, annular surface.

10. A light emitting diode (LED) package, comprising
an LED light source, and
an optical lens located over the LED light source, the optical lens comprising
a curved top surface, the top surface comprising a reflection surface located in the middle of the top surface and a refraction surface surrounding the reflection surface;
a bottom surface receiving the LED light source therein; and
a light reflective lateral surface interconnecting the bottom and top surfaces;
wherein the top surface receives light emitted from the LED light source, and the light striking the reflection surface is firstly reflected towards the lateral surface by the reflection surface, secondly reflected towards the refraction surface by the lateral surface, and finally refracted out of the optical lens by the refraction surface.

11. The light emitting diode (LED) package of claim 10, wherein a projection length of the reflection surface on a horizontal plane and along a radial direction of the optical lens is equal to that of the refraction surface.

12. The light emitting diode (LED) package of claim 10, wherein a middle of the bottom surface is concaved upwardly to define a receiving groove receiving the LED light source therein.

13. The light emitting diode (LED) package of claim 12, wherein the receiving groove defines a surface away from the bottom surface, and the surface is concaved upwardly and defines a cavity above the receiving groove.

14. The light emitting diode (LED) package of claim 13, wherein the cavity is semi-ellipsoid shaped.

15. The light emitting diode (LED) package of claim 14, wherein a length of a major axis of an ellipsoid defining the cavity which is along a central axis of the optical lens is 1.5-2.5 times of a length of a minor axis of the ellipsoid.

16. The light emitting diode (LED) package of claim 10, wherein the optical lens is symmetrically configured about a central axis of the optical lens, a middle of the top surface is recessed downward to a point, a peripheral portion around the point of the top surface is convex along an upward direction, and the central axis of the optical lens extends through the point.

17. The light emitting diode (LED) package of claim 16, wherein the reflection surface and the refraction surface cooperatively form a smooth, convex annular surface.

18. The light emitting diode (LED) package of claim 17, wherein the lateral surface is a smooth curve and concaved towards to the top surface, and the curvature radius of the lateral surface is greater than that of the annular surface.
